(19) United States
(12) Patent Application Publication
(10) Pub. No.: US 2002/0024103 A1
(43) Pub. Date: Feb. 28, 2002

(54) Structure of borderless contact and fabricating method thereof

(76) Inventors: Chang Yong Kang, Cheongju (KR); Seong Hyung Park, Cheongju (KR)

Correspondence Address: BIRCH STEWART KOLASCH & BIRCH, PO BOX 747, FALLS CHURCH, VA, 22040-0747, US

(21) Appl. No.: 09/939,594

(22) Filed: Aug. 28, 2001

(30) Foreign Application Priority Data
Aug. 29, 2000 (KR) 50459/2000

(51) Int. Cl. H01L 29/76; H01L 29/94

(52) U.S. Cl. 257/374; 257/401

(57) ABSTRACT

An improved borderless contact structure and method of making the structure including a substrate with side walls formed on the side of the shallow trench. An insulator is formed over the side walls and in the remainder of the trench such that the insulator extends above an upper surface of the substrate. The side walls are formed of a first etch selection type and the insulator is formed of a second etch selection type.

### BACKGROUND OF THE INVENTION

1. Field of the Invention

The present invention relates to an improved structure of a borderless contact and its fabricating method, and more particularly to a structure of a borderless contact in which a nitride film side wall is formed at a shallow trench isolation region.

2. Description of the Background Art

Conventionally, integrated circuits are designed with a boundary region near a region where a contact is formed during a fabricating process. The boundary region near the contact is used to prevent a contact opening from expanding by exceeding a region at which a contact is to be formed.

If a boundary region is not formed, a contact would be formed and depending upon variations in processes, the contact could extend into an adjacent region causing an undesirable connection. In this instance during subsequent processing, a field oxide would be removed due to over-etching and a leakage path may be formed from a metal to the substrate. Also, the over-etching of the field oxide may lead to over-etching of the silicon substrate.

Though the boundary near the contact opening guarantees proper registration of the contact and protection of lower conductive devices, it also brings about the negative affect that the maximum number of devices to be integrated is restricted

On the other hand, a borderless contact does not require a boundary near the contact, as is noted from the name, and thus, accomplishes improved chip integration. The borderless contact is formed by exposing an active region and an insulation region.

FIG. 1A is a sectional view depicting a structure of a borderless contact in accordance with a conventional art.

As shown in the drawing, a gate region 11 consisting of a gate 11a and a gate side wall 11b is formed on a substrate 10. An active region 12 is formed at a right lower portion of the gate region 11, and a field oxide 13 is formed next to the active region 12.

A nitride film 14 is deposited on the gate region 11, the active region 12 and the field oxide 13, and an interlayer dielectric film 15 is deposited on the nitride 14.

A contact opening 16 is formed in a portion of the interlayer dielectric 15, exposing the active region 12 and the field oxide 13. The contact opening 16 is filled with a conductive material in a subsequent process.

Since the nitride film 14 and the field oxide 13 each have etching selection ratios different from each other, the nitride film 14 serves as an etch stopper when the contact opening 16 is formed. However, when the nitride film 14 is used as an etch stopper, since the nitride film 14 is also deposited on the active region 12, it applies a stress to the active region 12, resulting in degradation of the device characteristic.

FIG. 1B is a sectional view showing a structure of a borderless contact without the use of a nitride film as an etch stopper and in accordance with the conventional art.

As shown in the drawing, when the contact opening 16 is formed at the interlayer dielectric film 15, since there is no etch stopper, the active region 12 and the field oxide 13 on the substrate 10 are over-etched.

Thus, in the case that an etch stopper of nitride film is not used, a problem of field recess arises due to lack of an etch stopper. To compensate for junction leakage which increases with the field recess, an ion-implantation is conducted to form a deep junction at the over-etched portion. In this case, however, its isolation characteristic is reduced.

### SUMMARY OF THE INVENTION

Therefore, an object of the present invention is to improve a device characteristic by providing a borderless contact structure in which no stress is applied to a substrate in spite of using a nitride film as an etch stopper.

To achieve these and other advantages and in accordance with the purpose of the present invention, as embodied and broadly described herein, there is provided an improved borderless contact structure including: a substrate having a shallow trench; side walls on the sides of the shallow trench; and an insulator over the side walls and in the remainder of the trench such that the insulator extends above an upper surface of the substrate. Additionally, the structure may have an oxide film having a thickness of less than 200 Å between the side wall and the substrate.

The side walls may be a nitride film and the insulator may be an oxide film. Also, the side walls are formed of a first etch selection type, while the insulator is formed of a second etch selection type.

The structure also includes active regions on either side of the shallow trench; gates over the substrate; and an interlayer dielectric film over the gates, active regions, insulator and substrate. Contact openings penetrate the interlayer 112 dielectric film and extend from the upper surface of the substrate to an upper surface of the interlayer dielectric film.

The contact opening may be entirely over an active area. The contact opening may also be in the shallow trench and partially in the insulator. When the contact opening is partially in the insulator, the contact opening does not extend lower than the active region or an upper surface of the side wall.

A second embodiment of the improved borderless contact structure includes a substrate having a shallow trench; side walls formed of a first etch selection type on sides of the shallow trench; and an insulator formed of a second etch selection type over the side walls and in the remainder of the trench. Additionally, the structure may have an oxide film having a thickness of less than 200 Å between the side walls and the substrate.

The side walls may be a nitride film and the insulator may be an oxide film.

The structure also includes active regions on either side of the shallow trench; gates over the substrate; and an interlayer dielectric film over the gates, active regions, insulator and substrate. Contact openings penetrate the interlayer dielectric film and extend from the upper surface of the substrate to an upper surface of the interlayer dielectric film.

The contact opening may be entirely over an active area. The contact opening may also be in the shallow trench and partially in the insulator. When the contact opening is partially in the insulator, the contact opening does not extend lower than the active region or an upper surface of the side wall.

Also, a portion of the insulator extends above the upper surface of the substrate.

In order to achieve the above object, there is also provided a method for fabricating a borderless contact structure including: forming a shallow trench in a substrate; forming sidewalls on the sides of the shallows trench; and forming an insulator over the sidewalls in the remainder of the trench such that the insulator extends above an upper surface of the substrate. The method may also include forming a thin oxide film having a thickness less than 200 Å between the sidewalls and the trench.

Photoresist may be deposited on the substrate and the trench formed in an area where a portion of the photoresist removed.

The method may also include removing the photoresist and forming a gate and an active region on the substrate; and depositing an interlayer dielectric film over the gate, active region and substrate.

Additionally, contact openings are formed in the interlayer dielectric film and the contact openings are filled with a conductive material. The contact openings are formed such that at least one contact opening extends from an upper surface of the interlayer dielectric film to the upper surface of the substrate. Further, a contact may be entirely over the active area or a contact opening may penetrate the insulator. When the contact opening penetrates the insulator, the sidewalls are used to prevent the contact opening from extending below the upper surface of the substrate.

Another embodiment of the invention provides a method for fabricating a borderless contact structure including: forming a shallow trench in a substrate; forming sidewalls having a first etch selection type on the sides of the shallow trench; and forming an insulator having a second etch selection type over the sidewalls in the remainder of the trench. The method may also include forming a thin oxide film having a thickness less than 200 Å between the sidewalls and the trench.

Photoresist may be deposited on the substrate and the trench formed in an area where a portion of the photoresist removed.

The method may also include removing the photoresist and forming a gate and an active region on the substrate; and depositing an interlayer dielectric film over the gate, active region and substrate.

Additionally, contact openings are formed in the interlayer dielectric film and the contact openings are filled with a conductive material. The contact openings are formed such that at least one contact opening extends from an upper surface of the interlayer dielectric film to the upper surface of the substrate. Further, a contact may be entirely over the active area or a contact opening may penetrate the insulator. When the contact opening penetrates the insulator, the sidewalls are used to prevent the contact opening from extending below the upper surface of the substrate.

The foregoing and other objects, features, aspects and advantages of the present invention will become more apparent from the following detailed description of the present invention when taken in conjunction with the accompanying drawings.

### BRIEF DESCRIPTION OF THE DRAWINGS

The accompanying drawings, which are included to provide a further understanding of the invention and are incorporated in and constitute a part of this specification, illustrate embodiments of the invention and together with the description serve to explain the principles of the invention.

In the drawings:

FIG. 1A is a sectional view depicting a structure of a borderless contact in accordance with a conventional art;

FIG. 1B is a sectional view depicting a structure of a borderless contact not using a nitride film as an etch stopper in accordance with the conventional art;

FIGS. 2A through 2C depict a series of processes for forming a nitride film side wall for an etch stopper in accordance with the present invention; and

FIG. 2D is a sectional view depicting a borderless contact structure in accordance with the present invention.

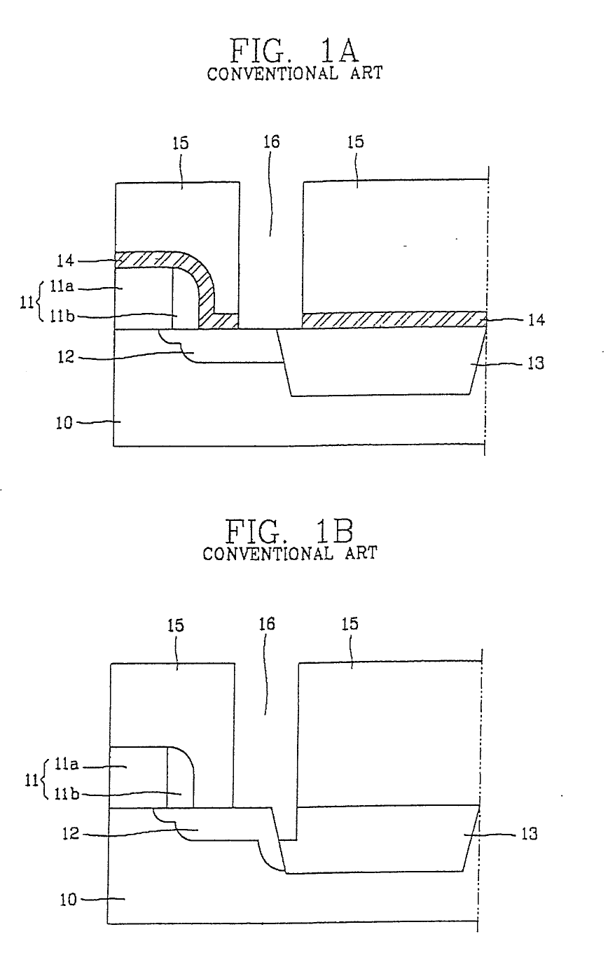

### DETAILED DESCRIPTION OF THE PREFERRED EMBODIMENTS

The present invention pertains to an improved borderIess contact structure including a substrate with a shallow trench structure that prevents a contact from being formed below the active region of the substrate.

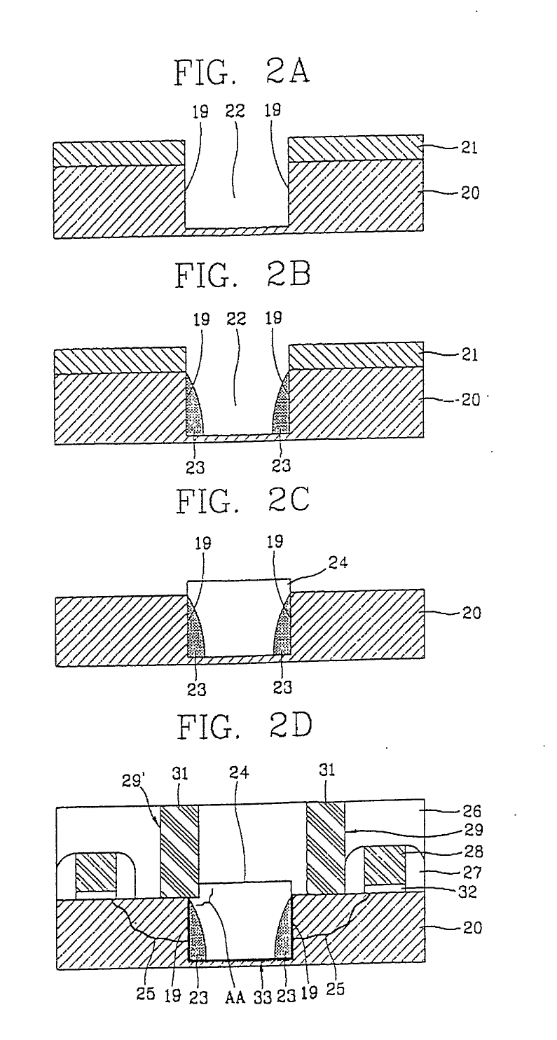

The shallow trench structure, as shown in FIG. 2C includes a substrate 20 with a shallow trench 22 formed therein and sidewalls 23 formed on the trench sides 19. Also, an insulator 24 is formed in the trench 22. The shallow trench structure serves as an insulator or field region between active regions 25 (see FIG. 20) of the substrate 20.

As shown in FIG. 2D, the upper surface of the substrate 20 includes gates 28. Gate insulators 32 are formed under the gates 28 and gate insulator side walls 27 are formed on the sides of the gates 28. An interlayer dielectric film 26 is formed over the substrate 20, gates 28 and insulator 24. Also, contact openings 29 and 29′ are formed in the interlayer dielectric film 26, and a conductive material 31 is formed in the contact openings 29 and 29′.

As shown in FIG. 2D, the contact openings 29 and 29′ may be formed on various positions of the substrate. For example, contact opening 29′ is formed entirely over the active region 25 while contact opening 29′ is misaligned with the active region 25 and formed partially in insulator 24 and partially over the active region 25. Sidewalls 23 prevent the field region corresponding to contact opening 29′ or other similarly situated field regions from forming below the active region 25.

An oxide film may be used as the insulator 24, and the upper portion of the insulator is formed higher than the active region, as shown in FIGS. 2C and 2D. If the insulator is formed lower than the active region, the active region is reduced in the width and a threshold voltage drops rapidly, causing degradation of the device characteristic. Such a narrowed-width effect can be prevented by maintaining the field region at a higher position in the active region.

Though side wall 23 is used as an etch stopper for a field oxide film in the process of the borderless contact, it exists only inside the field region. As a result, the degradation of device characteristic due to the stress applied to the silicon substrate by the nitride film as in the case of the conventional art can be improved. Further, side wall 23 may be composed of a nitride film or any other suitable etch stopper well known in the art.

FIGS. 2A through 2C show a series of processes for forming the shallow trench structure in accordance with the present invention.

With reference to FIG. 2A, after a photoresist 21 is deposited on a substrate 20, the photoresist 21 is partially removed. The substrate 20 at the region where the photoresist has been exposed is etched to form a shallow trench 22 with sides 19.

Next, with reference to FIG. 2B, a side wall 23 is formed at both sides 19 of the shallow trench 22. Before formation of the side wall 23, to alleviate the stress between the substrate 20 and the side wall 23, a thin oxide film 33 having a thickness of less than 200 Å may be formed in the trench structure.

With reference to FIG. 2C, after an insulator 24 or field oxide film is filled in the trench 22, etching by chemical mechanical polishing (CMP) is carried out. The insulator 24 is etched in a manner that the upper portion of the insulator 24 is maintained higher than the active region. During the CMP process, a slurry is used which selectively etches the substrate rather than the insulator 24 material. Thus, the photoresist 21 is removed and the insulator 24 remains.

As shown in FIG. 2D, the active region 25 and gates including gate 28, gate side wall 27, and gate insulator 32 are formed on the substrate 20. Also, an interlayer dielectric film 26 is deposited on the gates, the active region 25 and the insulator 24. Further, contact openings 29, 29′ are formed by etching into the interlayer dielectric film 26. If the etching of the contact opening 29 is misaligned as shown by contact opening 29′, the side wall 23 serves as an etch stopper. A conductive material 31 is filled in the contact openings 29, 29′, thereby completing a borderless contact structure.

As described, according to the borderless contact structure of the present invention, since the side wall 23 used as an etch stopper for the field oxide film is formed only at the inside of the field region, the degradation of device characteristic due to a stress applied by the side wall 23 to the silicon substrate can be improved. In other words, the nitride film formed, as an etch stopper, only at the side wall of the field oxide film contributes to reduce the stress applied to the active region, thereby remarkably improving a device characteristic and its reliability.

As the present invention may be embodied in several forms without departing from the spirit or essential characteristics thereof, it should also be understood that the above-described embodiments are not limited by any of the details of the foregoing description, unless otherwise specified, but rather should be construed broadly within its spirit and scope as defined in the appended claims, and therefore all changes and modifications that fall within the meets and bounds of the claims, or equivalence of such meets and bounds are therefore intended to be embraced by the appended claims.

What is claimed is:

1. An improved borderless contact structure comprising:
a substrate having a shallow trench;
side walls on sides of the shallow trench; and
an insulator formed over the side walls and in the remainder of the trench such that the insulator extends above an upper surface of the substrate.

2. The structure according to claim 1, wherein the insulator is an oxide film.

3. The structure according to claim 1, further comprising:
active regions on either side of the shallow trench;
gates over the substrate;
an interlayer dielectric film over the gates, active regions, insulator and substrate; and
contact openings penetrating the interlayer dielectric film, the contact openings extending from the upper surface of the substrate to an upper surface of the interlayer dielectric film.

4. The structure according to claim 1, further comprising:
an oxide film having a thickness of less then 200Å between the side wall and the substrate.

5. The structure according to claim 1, wherein the side wall is a nitride film.

6. The structure according to claim 1, wherein the side wall extends from the upper surface of the substrate to a lower surface of the shallow trench.

7. The structure according to claim 3, wherein at least one contact opening is entirely over the active region.

8. The structure according to claim 3, wherein at least one contact opening is partially in the insulator in the shallow trench; and
the contact opening does not extend lower than the active region or an upper surface of the side wall.

9. The structure of claim 1, wherein the side walls are formed of a first etch selection type; and
the insulator is formed of a second etch selection type.

10. An improved borderless contact structure comprising:
a substrate having a shallow trench;
side walls formed of a first etch selection type on sides of the shallow trench; and
an insulator formed of a second etch selection type over the side walls and in the remainder of the trench.

11. The structure according to claim 10, wherein the insulator is an oxide film.

12. The structure according to claim 10, further comprising:
active regions on either side of the shallow trench;
gates over the substrate;
an interlayer dielectric film over the gates, active regions, insulator and substrate; and
contact openings penetrating the interlayer dielectric film, the contact openings extending from the upper surface of the substrate to an upper surface of the interlayer dielectric film.

13. The structure according to claim 10, wherein the side wall is a nitride film.

14. The structure according to claim 10, farther comprising:
an oxide film having a thickness of less than 200 Å between the side wall and the substrate.

15. The structure acceding to claim 10, wherein the side wall extends from the upper surface of the substrate to a lower surface of the shallow trench.

16. The structure according to claim 12, wherein at least one contact opening is entirely over the active region.

17. The structure according to claim 12, wherein at least one contact opening is partially in the insulator in the shallow trench; and
the contact opening does not extend lower than the active region or an upper surface of the side wall.

18. The structure of claim 10, wherein a portion of the insulator extends above the upper surface of the substrate.

19. A method of fabricating a borderless contact structure comprising:
forming a shallow trench in a substrate;
forming side walls on sides of the shallow trench; and
forming an insulator over the side walls in the remainder of the trench such that the insulator extends above an upper surface of the substrate.

20. The method of claim 19, further comprising:
depositing photoresist on the substrate; and
removing a portion of the photoresist, wherein the shallow trench is formed where the photoresist has been removed.

21. The method of claim 20, further comprising:
removing the photoresist and forming a gate and an active region on the substrate;
depositing an interlayer dielectric film over the gate, active region, insulator and substrate;
forming a contact opening in the interlayer dielectric film; and
filling the contact opening with a conductive material.

22. The method of claim 19, further comprising:
depositing an interlayer dielectric film over the insulator and substrate; and
forming at least one contact opening in the interlayer dielectric film such that the contact opening extends from an upper surface of the substrate.

23. The method of claim 22, wherein the contact opening extends from an upper surface of the interlayer dielectric film to the upper surface of the substrate and the contact opening is entirely over the active area.

24. The method of claim 22, wherein
the contact opening extends from an upper surface of the interlayer dielectric film to an upper surface of the substrate and penetrates the insulator, and using the sidewalls to prevent the contact opening from extending below the upper surface of the substrate.

25. The method of claim 19, further comprising:
depositing photoresist on the substrate, removing a portion of the photoresist, wherein the shallow trench is formed in the region where the photoresist has been removed.

26. A method of fabricating a borderless contact structure comprising:
forming a shallow trench in a substrate;
forming side walls having a first etch selection type on sides of the shallow trench; and
forming an insulator having a second etch selection type over the side walls and in the remainder of the trench.

27. The method of claim 26, further comprising:
depositing photoresist on the substrate;
removing a portion of the photoresist;
wherein the shallow trench is formed in the region where the photoresist has been removed.

28. The method of claim 26, further comprising:
removing the photoresist and forming a gate and an active region on the substrate;
depositing an interlayer dielectric film over the gate, active region, insulator and substrate;
forming a contact opening in the interlayer dielectric film; and
filling the contact opening with a conductive material.

29. The method of claim 26, further comprising:
depositing an interlayer dielectric film over the insulator and substrate; and
forming at least one contact opening in the interlayer dielectric film such that the contact opening extends from an upper surface of the interlayer dielectric film to the upper surface of the substrate.

30. The method of claim 28, wherein the contact opening extends from an upper surface of the interlayer dielectric film to the upper surface of the substrate and the contact opening is entirely over the active area.

31. The method of claim 28, wherein the contact opening extends from an upper surface of the interlayer dielectric film to an upper surface of the substrate and penetrates the insulator, and using the sidewalls to prevent the contact opening from extending below the upper surface of the substrate.

32. The method of claim 26, further comprising:
forming a thin oxide film having a thickness of less than 200 Å in the trench, before the side walls are formed.
